(19) United States
(12) Patent Application Publication
(10) Pub. No.: US 2023/0411236 A1
(43) Pub. Date: Dec. 21, 2023

(54) PACKAGE STRUCTURE FOR POWER CONVERTOR AND MANUFACTURING METHOD THEREOF

(71) Applicant: Joulwatt Technology Co., Ltd., Hangzhou (CN)

(72) Inventor: Anda ZHANG, Hangzhou (CN)

(73) Assignee: Joulwatt Technology Co., Ltd., Hangzhou (CN)

(21) Appl. No.: 18/208,235

(22) Filed: Jun. 9, 2023

(30) Foreign Application Priority Data
Jun. 16, 2022 (CN) 202210686347.0

(51) Int. Cl. H01L 23/367; H01L 23/495; H01L 23/00; H01L 25/065; H01L 23/31

(52) U.S. Cl. CPC H01L 23/3677; H01L 23/49575; H01L 24/48; H01L 25/0657; H01L 23/3107; H01L 24/06; H01L 2924/1306; H01L 2924/1431; H01L 2224/48247; H01L 2224/48137; H01L 2224/0603; H01L 2225/0651; H01L 2225/06589

(57) ABSTRACT

The present disclosure provides a package structure and a package method for a power converter. The package structure includes at least one power device die and a control circuit die. The at least one power device die includes a first pad area and a support area on a first surface, and a second pad area on a second surface, wherein the first surface and the second surface are opposite each other. The control circuit die is on the support area of the at least one power device die. The package structure uses at least one power device die on the first surface to provide the support area to form a stacked structure, so as to reduce a chip area of the package structure and improve voltage resistance and heat dissipation performance of the chip.

### BACKGROUND OF THE DISCLOSURE

### Field of Technology

The present disclosure relates to a field of chip packaging, and specifically, to a package structure for a power converter and a manufacturing method thereof.

### Description of the Related Art

Semiconductor packaging process includes: placing a semiconductor die on a lead frame, connecting pads of the semiconductor die to pins of the lead frame by bonding wires, and covering the semiconductor die and part of the lead frame by encapsulant, so as to form a complete semiconductor chip that may be sold as a product. With development of packaging technology, system in package (SIP) technology has been adopted, in which a plurality of dies of active and/or passive devices are integrated into a single package structure. The system in package provides essentially complete system functionality in the single package structure, allowing not only for chip miniaturization, but also for reducing the number of peripheral components on the chip. For example, system-level packaging has been widely used in electronic devices such as smartphones.

However, in power converters, there are still considerable challenges in adopting system-level packaging. A power converter includes a control circuit and a power device, in which the power device is periodically turned on or off under control of the control circuit. In the power converter, an operating voltage of the power device (e.g., the source-drain voltage VDS of a field effect transistor) is higher than an operating voltage of the control circuit, and the power device may interfere with normal operation of the control circuit and may even cause damage to the control circuit due to high-voltage breakdown. In addition, the power device may generate a lot of heat, and if the package structure is poorly designed to dissipate heat will lead to deterioration of a thermal stability of the control circuit.

For example, a Chinese patent application 201580059661.4 of Texas Instruments, Inc. discloses an integrated package structure of a power converter, in which the control circuit and a plurality of power devices are laid flat on a silicon slab. The integrated package structure uses a tiled layout of a plurality of dies, which facilitates high-voltage isolation between the control circuit and the plurality of power devices, but the tiled layout of the control circuit and the plurality of power devices leads to an excessive chip area. Further, the integrated package structure uses the silicon plate as a separate support component, and the silicon plate is made by a patterning process to form a concave part to accommodate the chip, which not only leads to the high cost of the package structure, but also causes heat accumulation in the power device due to the silicon plate being set under the power device.

Therefore, it is expected to further improve the package structure of power converters to reduce chip area and improve chip reliability.

### SUMMARY OF THE INVENTION

In view of above problems, the present disclosure provides a package structure for a power converter and a manufacturing method thereof, in which a support area is provided on a first surface of a power device die to form a stacked structure, thereby reducing chip area of the package structure and improving voltage resistance and heat dissipation performance of the chip.

According to a first aspect of the present disclosure, there is provided a package structure for a power converter including at least one power device and a control circuit die. The at least one power device die includes a first pad area and a support area on a first surface, and a second pad area on a second surface, wherein the first surface and the second surface are opposite each other. The control circuit die is disposed on the support area of the at least one power device die.

Optionally, the first pad area at least partially surrounds the support area.

Optionally, the at least one power device includes a plurality of field effect transistors.

Optionally, the at least one power device includes a single die, the plurality of field effect transistors are formed in the single die.

Optionally, the at least one power device includes a plurality of dies, the plurality of field effect transistors are formed in the plurality of dies respectively.

Optionally, further including: a die pad for supporting an intermediate part of the control circuit die, wherein the plurality of dies support a peripheral part of the control circuit die.

Optionally, the die pad is cross-shaped, the plurality of dies are separated from each other by the die pad and are respectively connected to side edges of the die pad.

Optionally, source pads and gate pads of the plurality of field effect transistors are in the first pad area, and drain pads of the plurality of field effect transistors are in the second pad area.

Optionally, the source pads and gate pads of the plurality of field effect transistors are mirror symmetrical to each other.

Optionally, further including: an adhesive layer for fixing the control circuit die to the support area of the at least one power device die.

Optionally, a first set of pads of the control circuit die are connected to sources and gates of the plurality of field effect transistors inside the package structure.

Optionally, the at least one power device die further includes: at least one detection pad, wherein a set of pads of the control circuit die are connected to the at least one detection pad inside the package structure.

Optionally, the at least one detection pad provides a temperature detection signal and/or a current detection signal.

Optionally, further including: a lead frame including a plurality of pins, wherein inside the package structure, bonding wires are used to connect the plurality of pins of the lead frame to a second set of pads of the control circuit die and to sources of the plurality of field effect transistors.

Optionally, drain pads of the plurality of field effect transistors and the plurality of pins of the lead frame provide an external electrical connection for the package structure.

According to a second aspect of the present disclosure, there is provided a manufacturing method of a package structure for a power converter including following steps: forming at least one power device die; fixing a control circuit die on the at least one power device die; performing wire bonding to electrically connect the at least one power device die and the control circuit die to each other; and covering the at least one power device die and the control circuit die by encapsulant, wherein the at least one power device die includes a first pad area and a support area on a first surface, and a second pad area on a second surface, the first surface and the second surface are opposite each other, the support area of the at least one power device die provides a mounting surface for the control circuit die.

Optionally, wherein performing wire bonding includes: electrically connecting at least one of the at least one power device die and the control circuit die to a lead frame by a bonding wire.

Optionally, wherein at least one pad of the at least one power device die and a plurality of pins of the lead frame provide an external electrical connection for the package structure.

According to the package structure provided by embodiments of the resent disclosure, system-level package design is adopted to achieve chip miniaturization and reduce the number of peripheral components on the chip. In the system-level package design, setting the control circuit die on the power device die, so as to reduce a chip area, and performing wire bonding on pads inside the package structure, so as to reduce the number of external pins of the package structure.

Further, in this package structure, setting the pads of the power device die to be mirror symmetrical to each other to provide the support area as the mounting surface for the control circuit die, so that the power device die may double as a support component for the control circuit die. The package structure does not require separate support components or the patterning process associated with the support components, which not only saves manufacturing cost of the package structure by eliminating the support components, but also improves the heat dissipation performance of the chip by allowing direct exposure and use of the pads of the power device die for heat dissipation.

Further, in this package structure, the power device die is a vertical device with different pad areas located on two surfaces opposite to each other. By setting the control circuit die on the support area of the power device die, and setting high voltage pads of the power device die on the surface away from the control circuit die, voltage resistance of the package structure is improved with the stacked structure of the power device die 110 and the control circuit die 120.

In an optional embodiment, the support areas of a plurality of power device dies are used to provide the mounting surface of the control circuit die, the control circuit die with large size and the power device dies with small size are matched to each other, so as to provide better design freedom.

In an optional embodiment, the plurality of pins of the lead frame and the pads of the plurality of power device dies are used together to provide the external connection for the package structure, directly exposing the pads of the power device dies to improve the heat dissipation performance of the chip, and reducing the number of pins of the lead frame and bonding cost.

In an optional embodiment, die pad are used to support the control circuit die, so that not only the mechanical strength of the package structure is improved, but also the heat dissipation performance and the thermal stability of the control circuit die is improved by using the die pad with high thermal conductivity. The die pad that are additional are used to separate the plurality of power device dies, and thus distance between multiple dies may be used to improve pressure resistance of the package structure.

In an optional embodiment, a detection resistor is integrated into the power device die to detect a current flowing through the field effect transistor, and/or a temperature sensitive element is integrated to detect a temperature of the field effect transistor. A set of pads of the control circuit die and the detection pads of the power device die are connected inside the package structure, so that the control circuit die may achieve accurate over-current protection and over-temperature protection, further improving intelligence and integration of the system-level package design.

### BRIEF DESCRIPTION OF THE DRAWINGS

Through following description of embodiments of the present disclosure with reference to accompanying drawings, the above and other objectives, features, and advantages of the present disclosure will be more apparent, in the accompanying drawings:

FIG. 1 shows a schematic block diagram of a power converter.

FIGS. 2a and 2b show top view and bottom view of a power device die according to a first embodiment of the present disclosure respectively.

FIGS. 3a and 3b show top view and bottom view of a power device die according to a second embodiment of the present disclosure respectively.

FIGS. 4a and 4b show a three-dimensional view and a bottom view of a package structure according to a third embodiment of the present disclosure respectively.

FIGS. 5a and 5b show a three-dimensional view and a bottom view of a package structure according to a fourth embodiment of the present disclosure respectively.

FIGS. 6a to 6e show cross-sectional views of different stages of a manufacturing method of package structure according to a fifth embodiment of the present disclosure.

### DETAILED DESCRIPTION OF THE DISCLOSURE

The present disclosure is described below based on embodiments, but the disclosure is not limited to these embodiments. In the detailed description of the present disclosure below, some specific parts of the details are described in detail. The disclosure may be fully understood by those skilled in the art without the description of these detailed parts. In order to avoid confusion as to the substance of the present disclosure, well-known methods, processes, procedures, components and circuits are not described in detail.

Further, it should be understood by those of ordinary skill in the art that the accompanying drawings are provided herein for illustrative purposes and that the accompanying drawings are not necessarily drawn to scale. Unless the context clearly requires otherwise, the words “including”, “comprising”, and similar words throughout the specification and claims should be interpreted to mean inclusive rather than exclusive or exhaustive; that is, “including but not limited to”. In the description of the present disclosure, it is to be understood that the terms “first”, “second”, etc. are used for descriptive purposes only and are not to be construed as indicating or implying relative importance. In addition, in the description of the present disclosure, “plurality” means two or more unless otherwise specified.

The present disclosure may be presented in various forms, some embodiments of which are described below.

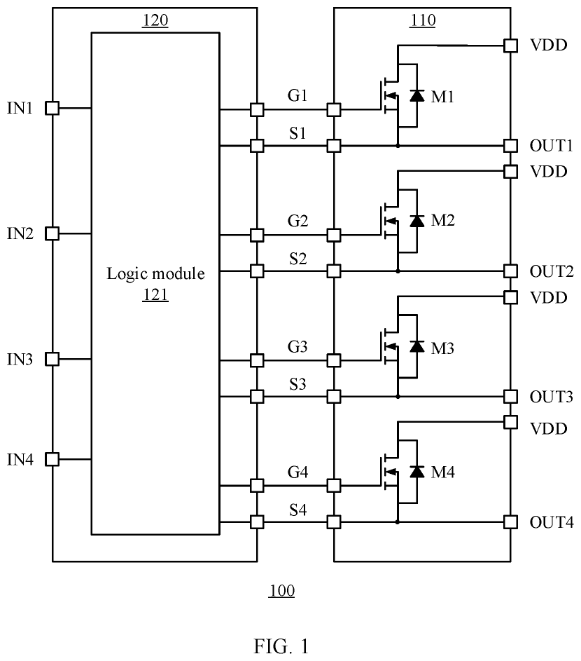

FIG. 1 shows a schematic block diagram of main components of a power converter. The power converter 100 includes a power device die 110, a control circuit die 120, and additional energy storage element. For example, the energy storage element includes an inductor and/or a capacitor.

The power device die 110 includes at least one power device. A plurality of power devices are connected to the energy storage element. During operation of the power converter, the energy storage element is periodically charged and discharged based on the switching control principle of the plurality of power devices, thereby generating a desired output voltage and/or output current at an output terminal of the power device die 110. The control circuit die 120 provides switching control signals for controlling on-state of the plurality of power devices.

The control circuit die 120 includes a logic module 121. the control circuit die 120 receives input signals IN1 to IN4 for a plurality of channels via input terminals and provides switching control signals G1 to G4 for the plurality of channels via output terminals. The control circuit die 120 may further include input terminals to receive detection signals S1 to S4 for the plurality of channels. Inside the control circuit die 120, the logic module 121 provides the switching control signals G1 to G4 according to the input signals IN1 to IN4 and the detection signals S1 to S4.

Although not shown in the drawings, the control circuit die 120 may further include additional detection module and protection module. The detection module receives the detection signals, which represent, for example, a current level, a temperature parameter, and an open-circuit parameter of the power device die 110. The detection module determines whether the power device die 110 is in an abnormal operation state such as overcurrent, overheating, or open-circuit according to the detection signals. The protection module is connected with the detection module and performs a protection action according to the abnormal operating state determined by the detection module. The protection module includes, for example, a bandgap circuit and a clamp circuit, wherein, when the power device die 110 is in the abnormal operating state, a bandgap voltage is generated by the bandgap circuit, so as to clamp the power device die 110 at a protection voltage associated with the bandgap voltage to achieve clamp protection.

In following embodiments, field effect transistors are described as examples of the power devices. In optional embodiments, the power device is, for example, a bipolar transistor. In a case that the field effect transistor serves as the power device, the power device die 110 receives the switching control signals G1 to G4 via the input terminals, a supply voltage VDD via a supply terminal, output signals OUT1 to OUT4 via the output terminals, and detection signals S1 to S4 representing source currents of the field effect transistors via the input terminals.

### First Embodiment

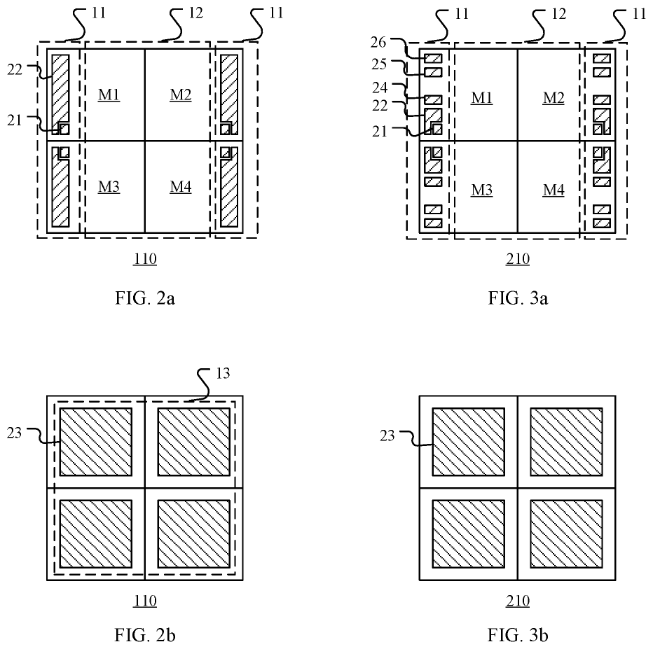

FIGS. 2a and 2b show top view and bottom view of a power device die according to a first embodiment of the present disclosure respectively.

The power device die 110 includes field effect transistors M1 to M4 formed on a semiconductor substrate. In the present embodiment, the semiconductor substrate is formed by monocrystalline silicon with a thickness of, for example, 50 microns. In alternative embodiments, the semiconductor substrate may be made by, for example, silicon-germanium, gallium arsenide, gallium nitride, or other III-V and II-IV compounds used as semiconductor device materials.

Inside the power device die 110, source regions, drain regions, and gate conductors of the field effect transistors M1 to M4 are formed respectively. In the present embodiment, the field effect transistors M1 to M4 are vertical devices including gate pads 21 and source pads 22 on a first surface of the power device die 110 and drain pads 23 on a second surface of the power device die 110. The pads 21, 22 and 23 of each field effect transistor of the field effect transistors M1 to M4 are connected to the gate conductor, the source region and drain region, respectively, and a channel current flowing in a thickness direction is provided in an on state of the field effect transistor. In an alternative embodiment, the field effect transistors M1 to M4 are vertical devices, respectively, with the source pads 22 and the drain pads 23 positioned interchangeably. In another alternative embodiment, the field effect transistors M1 to M4 are transverse devices, respectively, with a plurality of pads formed on the first surface connected to the gate conductor, the source regions and the drain regions, and the channel current flowing in a transverse direction is provided in the on state of the field effect transistor.

On the first surface of the power device die 110, the pads of each of the field effect transistors M1 to M4 are arranged asymmetrically, that is, the gate pads 21 and the source pads 22 of each of the field effect transistors M1 to M4 are located near the peripheral part of the first surface. The gate pads 21 and the source pads 22 of the field effect transistors M1 to M4 are mirror symmetrical to each other to collectively form a pad area 11 located at the peripheral part of the first surface. Further, the pad areas 11 of the field effect transistors M1 to M4 at least partially surround an intermediate part of the first surface to form a support area 12 for supporting the control circuit die 120.

On the second surface of the power device die 110, the pads of the field effect transistors M1 to M4 are uniformly distributed to form a pad area 13. For example, the drain pads 23 of the field effect transistor M1 are located on the pad area 13.

Optionally, the gate pads 21, the source pads 22 and the drain pads 23 of each of the field effect transistors M1 to M4 have different areas from each other. An area of the gate pad 21 may be smaller than an area of the source pad 22 depending on a characteristic of pads carrying different currents. An area of the drain pad 23 of the field effect transistor M1 may be larger than the area of the source pad 22, thereby providing sufficient heat dissipation area for the field effect transistor M1. In the field effect transistor M1, an operating voltage applied to the drain pad 23 is higher than an operating voltage applied to the source pad 21.

In the present embodiment, the pads of the field effect transistors M1 to M4 are formed in a mirror symmetrical shape to each other, thereby providing a support area 12 on the first surface of the power device die 110 as a mounting surface for the control circuit die 120, so that the power device die 110 may double as a support component for the control circuit die 120. Not only is manufacturing cost of the package structure saved by eliminating the support components, but the heat dissipation performance of the chip is also improved by allowing direct exposure and heat dissipation using the pads of the field effect transistors M1 to M4. Further, by using the power device die with a vertical device structure, high voltage pads of the power device die 110 may be designed on a surface away from the control circuit die 120, and a stacked structure of the power device die 110 and the control circuit die 120 may be used to improve voltage resistance of the package structure 100.

In the above embodiment, the single power device die 110 is described as including the plurality of field effect transistors M1 to M4, with the pads of the plurality of field effect transistors in the single power device die 110 forming a mirror symmetrical shape to each other to collectively provide the support area, thereby serving as the mounting surface for the control circuit die 120. In alternative embodiments, a plurality of power device dies 110 each include a single field effect transistor, and the plurality of power device dies 110 are adjacent to or spaced apart from each other and the pads of the plurality of field effect transistors form the mirror symmetrical shape with each other to collectively provide the support area, thereby serving as the mounting surface for the control circuit die 120.

### Second Embodiment

FIGS. 3a and 3b show top view and bottom view of a power device die according to a second embodiment of the present disclosure respectively.

The power device die 210 includes field effect transistors M1 to M4 formed on a semiconductor substrate. The field effect transistors M1 to M4 are vertical devices, respectively, including pads 21, 22 and 24 to 26 on a first surface of the power device die 210 and pads 23 on a second surface of the power device die 210, so as to provide a channel current flowing in a thickness direction.

The power device die 210 according to the second embodiment has essentially the same internal structure and pad layout as the power device die 210 according to the first embodiment, and only differences between the two are described below.

Inside the power device die 210, not only field effect transistors M1 to M4 are formed, but also a detection resistor and a temperature sensitive element are integrated. For example, the detection resistor is connected in series with a current terminal of the field effect transistor for converting a current flowing through the field effect transistor into a voltage signal, and the temperature sensitive element is, for example, a temperature sensitive resistor or a temperature sensitive transistor, adjacent to the field effect transistor, for converting the temperature near the field effect transistor into a voltage signal or a current signal. The detection resistor is integrated to detect the current flowing through the field effect transistor, and the temperature sensitive element is integrated to detect the temperature of the field effect transistor.

Additional detection pads 24 to 26 are formed in the pad area 11 on the first surface of the power device die 210. For example, the detection resistor is connected between the source pad 22 of the field effect transistor M1 and the detection pad 24, and the temperature sensitive resistor is connected between the detection pads 24 and 26. In the present embodiment, a set of pads of the control circuit die 120 is connected to the detection pads 24 to 26 of the power device die 210 inside the package structure, thus, the control circuit die 120 may achieve accurate over-current protection and over-temperature protection, further improving intelligence and integration of system-level package design.

### Third Embodiment

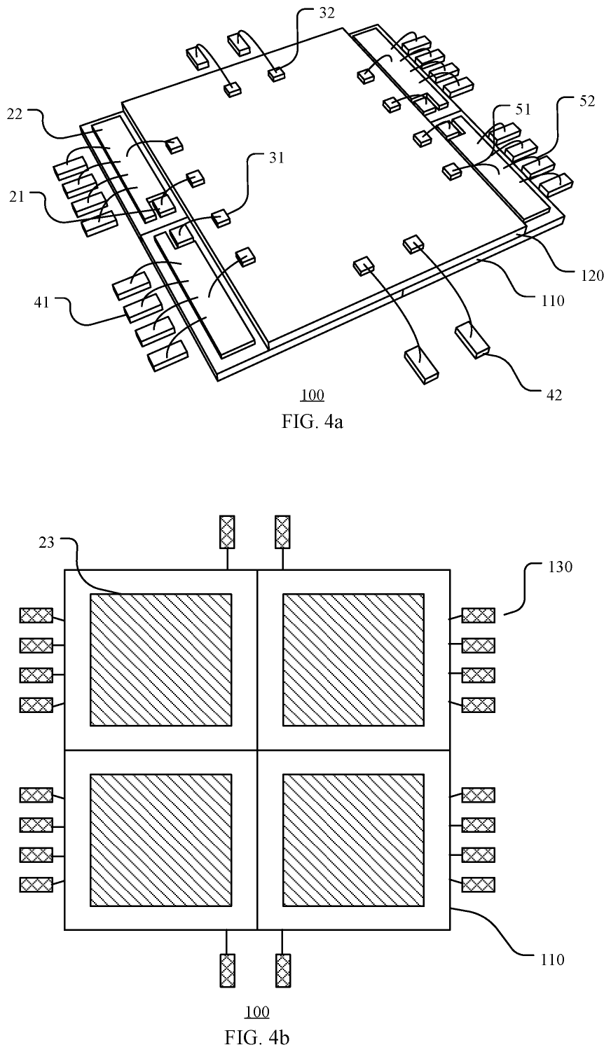

FIGS. 4a and 4b show a three-dimensional view and a bottom view of a package structure according to a third embodiment of the present disclosure respectively.

For clarity, encapsulant is not shown in the drawings so that the plurality of dies inside the package structure may be observed. It should be understood that in an actual package structure, the encapsulant will cover the power device die and the control circuit die and expose pins of a lead frame on a bottom and/or sides of the package structure for providing an external electrical connection.

The package structure 100 includes the power device die 110, the control circuit die 120, and the lead frame 130. The control circuit die 120 is stacked on the power device die 110. For example, an insulating bonding layer is used to fix the control circuit die 120 on the support area of the power device die 110. A first set of bonding wires 51 are used to electrically connect the control circuit die 120 and the power device die 110 to each other, and a second set of bonding wires 52 are used to electrically connect the control circuit die 120 and the power device die 110 to the lead frame 130, respectively.

Referring back to FIGS. 2a and 2b, the power device die 110 includes field effect transistors M1 to M4 formed on the single silicon substrate. The field effect transistors M1 to M4 are vertical devices, respectively, including the gate pads 21 and the source pads 22 located on the first surface of power device die 110 and the drain pads 23 located on a second surface of power device die 110, thereby allowing provide the channel current flowing in the thickness direction.

On the first surface of the power device die 110, the pads of each of the field effect transistors M1 to M4 are arranged asymmetrically, that is, the gate pads 21 and the source pads 22 of each of the field effect transistors M1 to M4 are located near the peripheral part of the first surface. Further, the gate pads 21 and the source pads 22 of the field effect transistors M1 to M4 are mirror symmetrical to each other to collectively form the pad area 11 located at the peripheral part of the first surface. Thus, flat surfaces of the field effect transistors M1 to M4 adjacent to each other together provide a large support area 12 as the mounting surface for the control circuit die 120.

With continued reference to FIGS. 4a and 4b, the control circuit die 120 includes the logic module, and optionally a detection module and a control module. A first set of pads 31 of the control circuit die 120 are connected to the gate pads 21 and source pads 22 of the field effect transistor in the power device die 110 via the first set of bonding wires 51, thereby providing the switching control signals to the gate pads 21 of the field effect transistor in the power device die 110 and receiving the detection signals from the source pads 22 of the field effect transistor in the power device die 110. A second set of pads 32 of the control circuit die 120 is used to receive external input signals. The logic module of the control circuit die 120 generates the switching control signals according to the input signals and the detection signals.

The lead frame 130 includes a first set of pins 41 and a second set of pins 42. The lead frame 130 may be composed of copper, for example, performing stamping to form a plurality of pins of the lead frame. The source pads 22 of the power device die 110 are connected to the first set of pins 41 of the lead frame 130 via the second set of bonding wires 52. The second set of pads 32 of the control circuit die 120 are connected to the second set of pins 42 of the lead frame 130 via the second set of bonding wires 52. In the present embodiment, the first set of pins 41 and the second set of pins 42 of the lead frame 130 are located on different sides of the package assembly 100. The first set of pins 41 and the second set of pins 42 are electrically isolated from each other by their different side positions, which improves the voltage resistance of the package structure 100.

Further, bottoms of the first set of pins 41 and the second set of pins 42 of the lead frame 130 and the drain pads 23 of the power device die 110 are flush.

In the present embodiment, the first set of pins 41 and the second set of pins 42 of the lead frame 130, and the drain pads 23 of the power device die 110 are all exposed at a bottom of the package structure 100, so as to provide the external electrical connection together. Further, directly exposing the drain pads 23 of the power device die 110 facilitates improvement of the thermal performance of the power device die 110. In alternative embodiments, the first set of pins 41 and the second set of pins 42 of the lead frame 130 extend from the sides of the package structure 100, and the drain pads 23 of the power device die 110 are exposed at the bottom of the package structure 100.

In the above embodiment, the single power device die 110 is described as including the plurality of field effect transistors M1 to M4, and the pads of the plurality of field effect transistors in the single power device die 110 form a mirror symmetrical shape with each other to collectively provide the support area, thereby serving as the mounting surface for the control circuit die 120.

### Fourth Embodiment

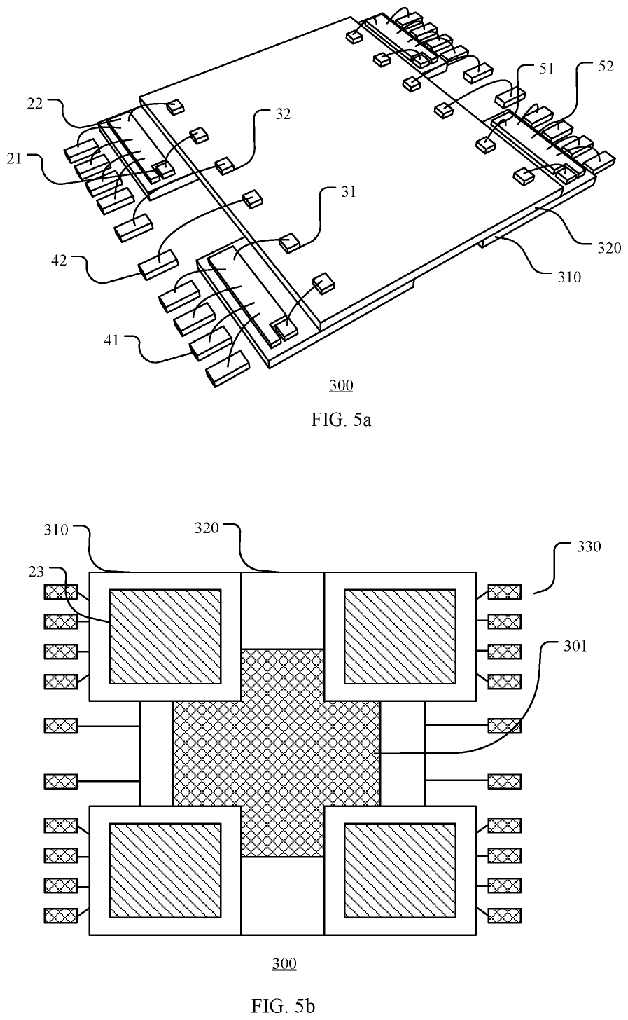

FIGS. 5a and 5b show a three-dimensional view and a bottom view of a package structure according to a fourth embodiment of the present disclosure respectively.

For clarity, encapsulant is not shown in the drawings so that the plurality of dies inside the package structure may be observed. It should be understood that in an actual package structure, the encapsulant will cover the power device die and the control circuit die and expose pins of a lead frame on a bottom and/or sides of the package structure for providing an external electrical connection.

The package structure 300 includes the plurality of power device dies 310, the control circuit die 320, the lead frame 330, and a die pad 301. The control circuit die 320 is stacked on top of power device dies 310. For example, the insulating bonding layer is used to fix the control circuit die 320 on the support area formed by the plurality of power device dies 310. The first set of bonding wires 51 are used to electrically connect the control circuit die 320 and the plurality of power device dies 310 to each other, and the second set of bonding wires 52 are used to electrically connect the control circuit die 320 and the plurality of power device dies 310 to the lead frame 330, respectively.

In the present embodiment, the plurality of power device dies 310 are separated from each other. In plurality of power device dies 310, a semiconductor substrate is used to form the single field effect transistor, respectively. The field effect transistors M1 to M4 are vertical devices, respectively, including the gate pads 21 and the source pads 22 located on the first surface of a corresponding power device die 310, and the drain pads 23 located on the second surface of the corresponding power device die 310, thereby providing the channel current flowing in the thickness direction.

On the first surface of the power device die 310, the pads of each of the field effect transistors M1 to M4 are arranged asymmetrically, that is, the gate pads 21 and source pads 22 of each of the field effect transistors M1 to M4 are located close to a side of the first surface of the corresponding power device die 310 to form the pad area 11 located on the side part of the first surface of the corresponding power device die 310, respectively. Further, the gate pads 21 and source pads 22 of the field effect transistors M1 to M4 form a mirror symmetrical shape to each other. Thus, flat surfaces of the field effect transistors M1 to M4 adjacent to each other together provide a large support area as the mounting surface for the control circuit die 320.

With continued reference to FIGS. 5a and 5b, the control circuit die 320 includes the logic module, and optionally the detection module and the control module. The first set of pads 31 of the control circuit die 320 are connected to the gate pads 21 and source pads 22 of the field effect transistor in the power device die 310 via the first set of bonding wires 51, thereby providing the switching control signals to the gate pads 21 of the field effect transistor in the power device die 310 and receiving the detection signals from the source pads 22 of the field effect transistor in the power device die 310. The second set of pads 32 of the control circuit die 320 is used to receive the external input signals. The logic module of the control circuit die 320 generates the switching control signals according to the input signals and the detection signals.

The die pad 301 includes a first surface and a second surface opposite each other. The first surface of the die pad 301 is flush with the first surface of the plurality of power device dies 310, providing the mounting surface for the control circuit die 320 along with the support area of the plurality of power device dies 310. The second surface of the die pad 301 is flush with the bottom of the drain pads 23 of the plurality of power device dies 310 and is exposed to the bottom of the package structure, thereby providing a heat dissipation path for the control circuit die 320. For example, the control circuit die 320 is fixed on the first surface of the die pad 301 by the insulating bonding layer.

The die pad 301 is disposed between the plurality of power device dies 310, so as to separate the plurality of power device dies 310 from each other. Optionally, the die pad 301 is cross-shaped, the cross-shaped including a middle part of a square and a branching part extending vertically from sides of the middle part. The sides of the branched part of the die pad 301 are adjacent to the plurality of power device dies 310.

The lead frame 330 includes the first set of pins 41 and the second set of pins 42. The lead frame 130 may include copper, for example, performing stamping to form the plurality of pins of the lead frame. The source pads 22 of the power device die 310 are connected to the first set of pins 41 of the lead frame 330 via the second set of bonding wires 52. the second set of pads 32 of the control circuit die 320 are connected to the second set of pins 42 of the lead frame 330 via the second set of bonding wires 52. In the present embodiment, the pin spacing between the plurality of pins of the lead frame 330 is sufficiently large to provide the desired voltage resistance. The first set of pins 41 and the second set of pins 42 are located on the same side of the package assembly 300.

Further, the bottoms of the first set of pins 41 and the second set of pins 42 of the lead frame 330, the die pad 301, and the drain pad 23 of the power device die 310 are flush.

In the present embodiment, the first set of pins 41 and the second set of pins 42 of lead frame 130, and the drain pads 23 of power device die 110 are all exposed at the bottom of the package structure 300, so as to provide the external electrical connection together. Further, directly exposing the drain pads 23 of the power device die 110 facilitates improvement of the thermal performance of the power device die 310. Exposing the die pad 301 on the bottom of the package structure 300 facilitates improvement of the thermal performance of the control circuit die 320. In alternative embodiments, the first set of pins 41 and the second set of pins 42 of the lead frame 330 extend from the sides of the package structure 300, and the die pad 301 and the drain pads 23 of the power device die 310 are exposed at the bottom of the package structure 300.

In the above embodiment, the plurality of power device dies 310 are described as each including the single field effect transistor, with the plurality of power device dies 310 separated from each other and the pads of the plurality of field effect transistors forming a mirror symmetrical shape to each other. The plurality of power device dies 310 and die pad 301 together provide the support area, thereby serving as the mounting surface for the control circuit die 320.

### Fifth Embodiment

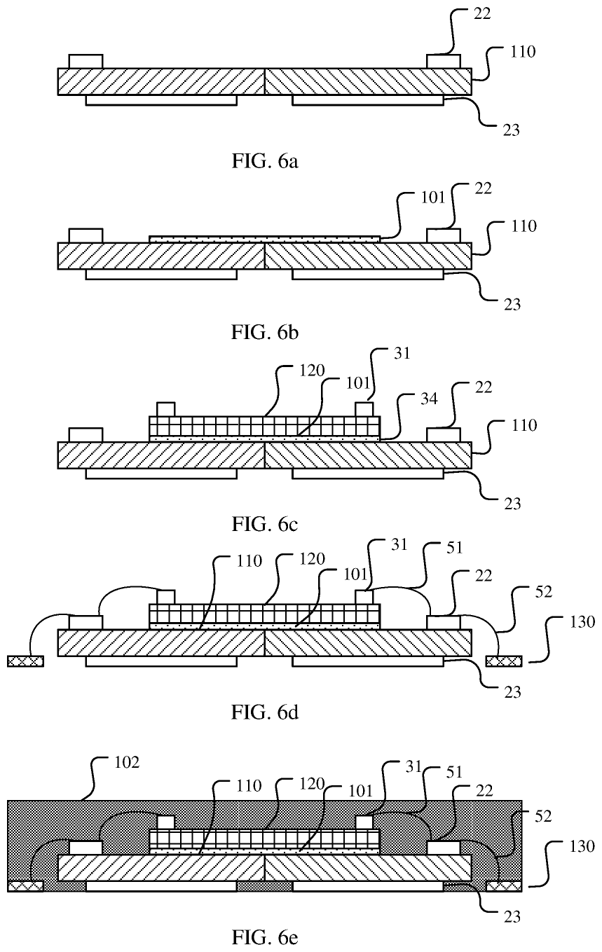

FIGS. 6a to 6e show cross-sectional views of different stages of a manufacturing method of package structure according to a fifth embodiment of the present disclosure. The fabrication method is used, for example, to form the package structure according to the third embodiment of the present disclosure.

In step S01, forming a power device die 110 with a support area, as shown in FIG. 6a.

The power device die 110 includes field effect transistors M1 to M4 formed on a single semiconductor substrate. The field effect transistors M1 to M4 are vertical devices including gate pads 21 and source pads 22 located on a first surface of the power device die 110, and drain pads 23 located on a second surface of the power device die 110, thereby providing channel current flowing in a thickness direction.

On the first surface of the power device die 110, the pads of each of the field effect transistors M1 to M4 are arranged asymmetrically, that is, the gate pads 21 and source pads 22 of each of the field effect transistors M1 to M4 are located near a peripheral part of the first surface. Further, the gate pads 21 and source pads 22 of the field effect transistors M1 to M4 form a mirror symmetrical shape with each other to collectively form a pad area 11 located at the peripheral part of the first surface. Thus, flat surfaces of the field effect transistors M1 to M4 adjacent to each other together provide a large support area 12 as the mounting surface for the control circuit die 120.

In step S02, forming an insulating bonding layer on the support area of the power device die 110, as shown in FIG. 6b.

In this step, the insulating bonding layer 101 is formed on the support area of the power device die 110 by a dispensing process, and an epoxy resin layer formed by a single dispensing process has a thickness of about 10 microns. A desired thickness of the insulation bonding layer 101 may be obtained by multiple dispensing processes. The insulating bonding layer 101 is, for example, epoxy resin.

In step S03, fixing the control circuit die 120 to the support area of the power device die 110, as shown in FIG. 6c.

In this step, the control circuit die 120 is arranged on the insulating bonding layer 101. Fixation of the control circuit die 120 is achieved after the insulating bonding layer 101 is cured.

A position of the control circuit die 120 is aligned with the support area of the power device die 110. The control circuit die 120 is stacked on top of the power device die 110. Gate pads 21 and source pads 22 of the field effect transistors M1 to M4 in the power device die 110 surround the control circuit die 120.

In step S04, performing wire bonding to connect the power device die 110 and the control circuit die 120 to the lead frame, as shown in FIG. 6d.

In this step, a first set of bonding wires 51 is used to connect a first set of pads 31 of the control circuit die 120 to the gate pads 21 and the source pads 22 of the field effect transistor in the power device die 110, and a second set of bonding wires 52 are used to electrically connect the control circuit die 120 and the power device die 110 to the lead frame 130, respectively. Since the gate pads 21 and source pads 22 of the power device die 110 are adjacent to sides of the control circuit die 120, a length of the first set of bonding wires 51 may be reduced, thereby reducing parasitic effects.

In step S05, covering i the power device die 110 and the control circuit die 120 by encapsulant, as shown in FIG. 6e.

In this step, depending on material of the encapsulant, it may be divided into resin encapsulation and ceramic encapsulation. In a case of resin encapsulation, the power device die 110 and control circuit die 120 are placed in a mold together with the lead frame, and molten resin is extruded into the mold, and the resin covers the power device die 110 and control circuit die 120, as well as covers bonding wires. The package structure 100 is formed after the resin has cured.

A plurality of pins of the lead frame 130 and the drain pads 23 of the power device die 110 are exposed at the bottom of the package structure 100, thus providing an external electrical connection together. Further, directly exposing of the drain pads 23 of the power device die 110 facilitates improvement of the thermal performance of the power device die 110.

The above description is only a preferred embodiment of the present disclosure and is not intended to limit the present disclosure, which is subject to various modifications and variations for those skilled in the art. Any modification, equivalent replacement, improvement, etc. made within the spirit and principle of the present disclosure shall be included in the scope of protection of the present disclosure.

1. A package structure for a power converter, comprising:
at least one power device die comprising a first pad area and a support area on a first surface, and
a second pad area on a second surface, wherein the first surface and the second surface are opposite each other; and
a control circuit die disposed on the support area of the at least one power device die.

2. The package structure according to claim 1, wherein the first pad area at least partially surrounds the support area.

3. The package structure according to claim 1, wherein the at least one power device comprises a plurality of field effect transistors.

4. The package structure according to claim 3, wherein the at least one power device comprises a single die, the plurality of field effect transistors are formed in the single die.

5. The package structure according to claim 3, wherein the at least one power device comprises a plurality of dies, the plurality of field effect transistors are formed in the plurality of dies respectively.

6. The package structure according to claim 5, further comprising:
a die pad for supporting an intermediate part of the control circuit die, wherein the plurality of dies support a peripheral part of the control circuit die.

7. The package structure according to claim 6, wherein the die pad is cross-shaped, the plurality of dies are separated from each other by the die pad and are respectively connected to side edges of the die pad.

8. The package structure according to claim 3, wherein source pads and gate pads of the plurality of field effect transistors are in the first pad area, and drain pads of the plurality of field effect transistors are in the second pad area.

9. The package structure according to claim 8, wherein the source pads and gate pads of the plurality of field effect transistors are mirror symmetrical to each other.

10. The package structure according to claim 3, further comprising:
an adhesive layer for fixing the control circuit die to the support area of the at least one power device die.

11. The package structure according to claim 3, wherein a first set of pads of the control circuit die are connected to sources and gates of the plurality of field effect transistors inside the package structure.

12. The package structure according to claim 3, wherein the at least one power device die further comprises: at least one detection pad,
wherein a set of pads of the control circuit die are connected to the at least one detection pad inside the package structure.

13. The package structure according to claim 12, wherein the at least one detection pad provides a temperature detection signal and/or a current detection signal.

14. The package structure according to claim 3, further comprising:
a lead frame comprising a plurality of pins,
wherein inside the package structure, bonding wires are used to connect the plurality of pins of the lead frame to a second set of pads of the control circuit die and to sources of the plurality of field effect transistors.

15. The package structure according to claim 14, wherein drain pads of the plurality of field effect transistors and the plurality of pins of the lead frame provide an external electrical connection port for the package structure.

16. A manufacturing method of a package structure for a power converter, comprising:
forming at least one power device die;
fixing a control circuit die on the at least one power device die;
performing wire bonding to electrically connect the at least one power device die and the control circuit die to each other; and
covering the at least one power device die and the control circuit die by encapsulant,
wherein the at least one power device die comprises a first pad area and a support area on a first surface, and a second pad area on a second surface, the first surface and the second surface are opposite each other, the support area of the at least one power device die provides a mounting surface for the control circuit die.

17. The manufacturing method of the package structure according to claim 16, wherein
performing wire bonding comprises: electrically connecting at least one of the at least one power device die and the control circuit die to a lead frame by a bonding wire.

18. The manufacturing method of the package structure according to claim 17, wherein at least one pad of the at least one power device die and a plurality of pins of the lead frame provide an external electrical connection port for the package structure.
